(19) United States
(12) Patent Application Publication
(10) Pub. No.: US 2025/0079245 A1
(43) Pub. Date: Mar. 6, 2025

(54) CERAMIC SUBSTRATE, LIGHT SOURCE DEVICE, METHOD OF MANUFACTURING CERAMIC SUBSTRATE, AND METHOD OF MANUFACTURING LIGHT SOURCE DEVICE

(71) Applicant: NICHIA CORPORATION, Anan-shi (JP)

(72) Inventors: Norifumi SASAOKA, Tokushima-shi (JP); Shoichi YAMADA, Anan-shi (JP); Akiko NAGAE, Tokushima-shi (JP)

(73) Assignee: NICHIA CORPORATION, Anan-shi (JP)

(21) Appl. No.: 18/797,441

(22) Filed: Aug. 7, 2024

(30) Foreign Application Priority Data
Sep. 6, 2023 (JP) 2023-144492
Mar. 25, 2024 (JP) 2024-048003

(51) Int. Cl. H01L 23/15; H01L 21/02; H01L 33/62

(52) U.S. Cl. CPC H01L 23/15; H01L 21/02389; H10H 20/857

(57) ABSTRACT

A ceramic substrate including a base having a first surface, a second surface opposite to the first surface, and a through hole having a first opening diameter at the first surface and a second opening diameter at the second surface. The first opening diameter is larger than the second opening diameter. The ceramic substrate also includes at least one solid particle disposed in the through hole, and an electrically-conductive member disposed in the through hole. A thermal conductivity of the at least one solid particle is higher than a thermal conductivity of the electrically-conductive member. The electrically-conductive member is continuous between the first surface and the second surface.

### CROSS-REFERENCE TO RELATED APPLICATIONS

The present application claims priority under 35 U.S.C. § 119 to Japanese Patent Application No. 2023-144492, filed Sep. 6, 2023, and Japanese Patent Application No. 2024-048003, filed Mar. 25, 2024, the contents of which are hereby incorporated by reference in their entirety.

### BACKGROUND

### 1. Technical Field

The present disclosure relates to a ceramic substrate, a light source device, a method of manufacturing a ceramic substrate, and a method of manufacturing a light source device.

### 2. Description of Related Art

Japanese Patent Publication No. 2003-115658 describes an element package that includes a wiring substrate including a ceramic substrate having a through hole and an electrically-conductive member provided in the through hole. In the element package, the conductive member and an element are electrically connected to each other.

In the ceramic substrate, a portion of generated heat is released through the electrically-conductive member, and thus further improvement in the heat dissipation of the ceramic substrate is required.

### SUMMARY

Embodiments of the present disclosure can advantageously provide a ceramic substrate that can improve heat dissipation, a light source device, a method of manufacturing a ceramic substrate, and a method of manufacturing a light source device.

According to one aspect of the present disclosure, a ceramic substrate includes a base having a first surface, a second surface opposite to the first surface, and a through hole having a first opening diameter at the first surface and a second opening diameter at the second surface, the first opening diameter being larger than the second opening diameter; at least one solid particle disposed in the through hole; and an electrically-conductive member disposed in the through hole, wherein a thermal conductivity of the at least one solid particle is higher than a thermal conductivity of the electrically-conductive member, and the electrically-conductive member is continuous between the first surface and the second surface.

According to another aspect of the present disclosure, a method of manufacturing a ceramic substrate includes preparing a base having a first surface, a second surface opposite to the first surface, and a through hole having a first opening diameter at the first surface and a second opening diameter at the second surface, the first opening diameter being larger than the second opening diameter; disposing at least one solid particle in the through hole from a first surface side of the base; disposing an electrically-conductive paste in the through hole after the disposing of the at least one solid particle in the through hole; and forming an electrically-conductive member that is continuous between the first surface and the second surface by sintering the electrically-conductive paste, wherein a thermal conductivity of the at least one solid particle is higher than a thermal conductivity of the electrically-conductive member.

### BRIEF DESCRIPTION OF THE DRAWINGS

Amore complete appreciation of embodiments of the invention and many of the attendant advantages thereof will be readily obtained by reference to the following detailed description when considered in connection with the accompanying drawings.

FIG. 1 is a top view illustrating a ceramic substrate according to a first embodiment.

FIG. 2A is a cross-sectional view of the ceramic substrate according to the first embodiment, taken through line IIa-IIa of FIG. 1.

FIG. 2B is a cross-sectional view of the ceramic substrate according to the first embodiment, taken through line IIb-IIb of FIG. 1.

FIG. 3A is a cross-sectional view illustrating an example of a solid particle.

FIG. 3B is a cross-sectional view illustrating an example of a solid particle.

FIG. 3C is a cross-sectional view illustrating an example of a solid particle.

FIG. 4A is a top view illustrating the shape of inner lateral surfaces defining a through hole in a plan view.

FIG. 4B is a top view illustrating the shape of inner lateral surfaces defining a through hole in a plan view.

FIG. 4C is a top view illustrating the shape of inner lateral surfaces defining a through hole in a plan view.

FIG. 4D is a top view illustrating the shape of inner lateral surfaces defining a through hole in a plan view.

FIG. 4E is a top view illustrating the shape of inner lateral surfaces defining a through hole in a plan view.

FIG. 5A is a cross-sectional view illustrating the arrangement of solid particles in a through hole.

FIG. 5B is a cross-sectional view illustrating the arrangement of solid particles in a through hole.

FIG. 5C is a cross-sectional view illustrating the arrangement of solid particles in a through hole.

FIG. 6 is a cross-sectional view illustrating a method of manufacturing the ceramic substrate according to the first embodiment.

FIG. 7 is a cross-sectional view illustrating the method of manufacturing the ceramic substrate according to the first embodiment.

FIG. 8 is a cross-sectional view illustrating the method of manufacturing the ceramic substrate according to the first embodiment.

FIG. 9 is a cross-sectional view illustrating the method of manufacturing the ceramic substrate according to the first embodiment.

FIG. 10 is a cross-sectional view illustrating the method of manufacturing the ceramic substrate according to the first embodiment.

FIG. 11 is a cross-sectional view illustrating the method of manufacturing the ceramic substrate according to the first embodiment.

FIG. 12 is a cross-sectional view illustrating the method of manufacturing the ceramic substrate according to the first embodiment.

FIG. 13 is a cross-sectional view illustrating an example of a method of disposing a solid particle in a through hole.

FIG. 14 is a cross-sectional view illustrating an example of a method of disposing an electrically-conductive paste.

FIG. 15 is a cross-sectional view illustrating a ceramic substrate according to a second embodiment.

FIG. 16 is a cross-sectional view illustrating a method of manufacturing the ceramic substrate according to the second embodiment.

FIG. 17 is a cross-sectional view illustrating the method of manufacturing the ceramic substrate according to the second embodiment.

FIG. 18 is a cross-sectional view illustrating the method of manufacturing the ceramic substrate according to the second embodiment.

FIG. 19 is a cross-sectional view illustrating the method of manufacturing the ceramic substrate according to the second embodiment.

FIG. 20 is a cross-sectional view illustrating the method of manufacturing the ceramic substrate according to the second embodiment.

FIG. 21 is a cross-sectional view illustrating a light source device according to a third embodiment.

### DETAILED DESCRIPTION

Embodiments of the present disclosure will be described below with reference to the accompanying drawings. The following description is provided for the purpose of embodying the technical ideas of the present disclosure, but the present disclosure is not limited to the embodiments in the following description unless specifically stated.

In the drawings, members having the same functions may be denoted by the same reference numerals. In consideration of ease of explanation or ease of understanding of key points, configurations may be illustrated in separate embodiments for the sake of convenience; however, such configurations illustrated in different embodiments or examples can be partially substituted or combined with one another. A description of an embodiment given after a description of another embodiment will be focused mainly on matters different from those of the previously described embodiment, and a duplicate description of matters common to the previously described embodiment may be omitted. The sizes, positional relationships, and the like of members illustrated in the drawings may be exaggerated for clearer illustration. An end view illustrating only a cut surface may be used as a cross-sectional view.

In the present specification, the expression “in a plan view” refers to viewing an object from the first surface side or the second surface side of a base of a ceramic substrate. A surface of the object as viewed from the first surface side of the base of the ceramic substrate may be referred to as an upper surface, and a surface opposite to the upper surface may be referred to as a lower surface.

### First Embodiment

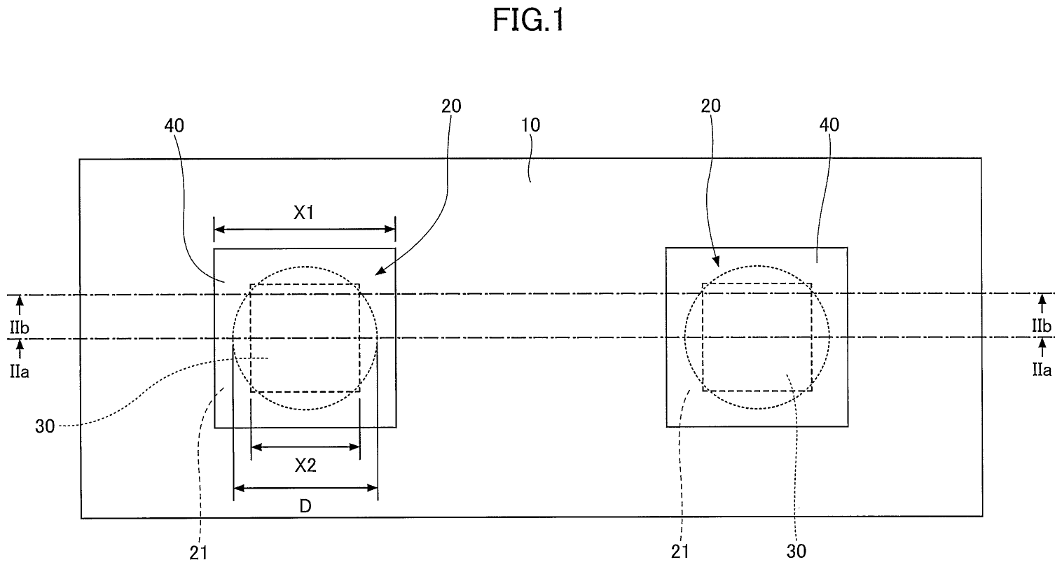

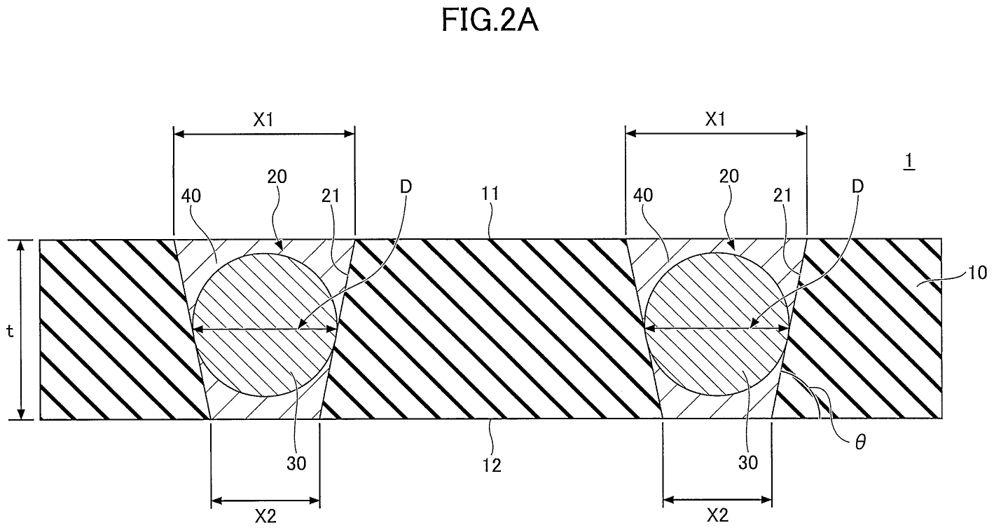

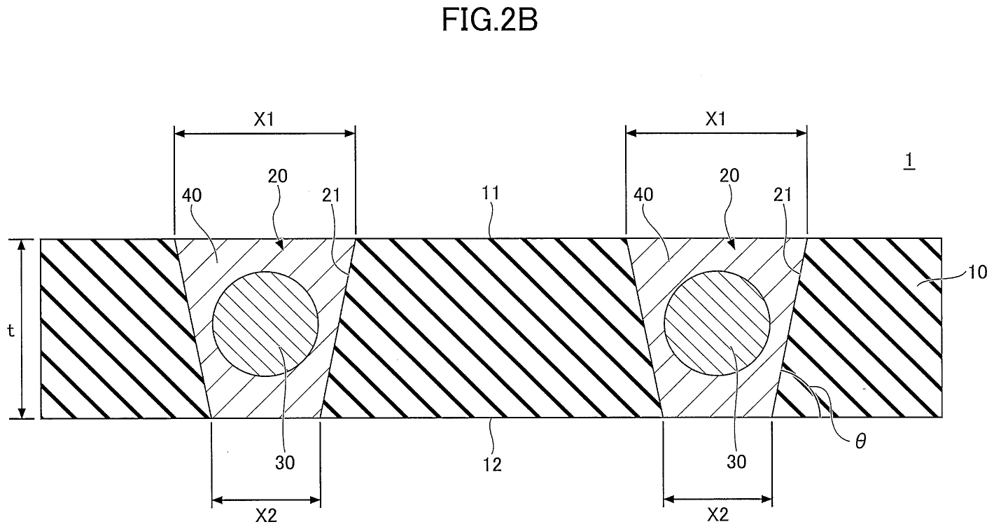

A first embodiment will be described. The first embodiment relates to a ceramic substrate. FIG. 1 is a top view illustrating the ceramic substrate according to the first embodiment. FIG. 2A and FIG. 2B are cross-sectional views illustrating the ceramic substrate according to the first embodiment. FIG. 2A is a cross-sectional view taken through line IIa-IIa of FIG. 1. FIG. 2B is a cross-sectional view taken through line IIb-IIb of FIG. 1.

As illustrated in FIG. 1, FIG. 2A, and FIG. 2B, a ceramic substrate 1 according to the first embodiment includes a base 10, a solid particle 30, and an electrically-conductive member 40.

The base 10 is an insulating base and has a first surface 11 and a second surface 12 opposite to the first surface 11. The base 10 is, for example, a ceramic. For example, if the material of the base 10 is silicon nitride (Si₃N₄), a thickness t of the base 10 is 100 μm or more and 320 μm or less. If the material of the base 10 is aluminum nitride (AlN), the thickness t of the base 10 is 100 μm or more and 1,000 μm or less. At least one through hole 20 penetrating between the first surface 11 and the second surface 12 is formed in the base 10. For example, the through hole 20 has a square shape in a plan view. The shape of a cross-section perpendicular to a direction toward the center of the through hole 20 in a plan view (hereinafter can be referred to as the “shape of inner lateral surfaces defining the through hole 20 in a plan view”) is also a square shape. The through hole 20 has inner lateral surfaces 21 that are continuous from the first surface 11 to the second surface 12. The through hole 20 has a first opening diameter X1 at the first surface 11 and a second opening diameter X2 at the second surface 12, and the first opening diameter X1 is larger than the second opening diameter X2. The first opening diameter X1 corresponds to the diameter of the largest imaginary circle included in a figure formed by the outline on the first surface 11 side of the through hole 20. The second opening diameter X2 corresponds to the diameter of the largest imaginary circle included in a figure formed by the outline on the second surface 12 side of the through hole 20. The opening diameter of the through hole 20 continuously increases from the second surface 12 to the first surface 11. For example, each of the inner lateral surfaces 21 is inclined at an angle θ of 80° or more and 89° or less with respect to the second surface 12, and is preferably inclined at an angle θ of 83° or more and 86° or less with respect to the second surface 12. If the thickness t of the base 10 is 100 μm or more and 320 μm or less, for example, the first opening diameter X1 is 85 μm or more and 290 μm or less, and the second opening diameter X2 is 65 μm or more and 250 μm or less.

The electrically-conductive member 40 is disposed in the through hole 20, and the electrically-conductive member 40 is continuous between the first surface 11 and the second surface 12. The solid particle 30 is embedded in the electrically-conductive member 40. The phrase “the solid particle 30 is embedded in the electrically-conductive member 40” means that the entire surface of the solid particle 30 is covered by the electrically-conductive member 40. The electrically-conductive member 40 contacts the solid particle 30. Because the electrically-conductive member 40 contacts the solid particle 30, a heat transfer path can be formed as described below. The thermal conductivity of the solid particle 30 is higher than the thermal conductivity of the electrically-conductive member 40. For example, the electrically-conductive member 40 includes sintered copper or sintered silver. The electrically-conductive member 40 can include a titanium compound. The electrically-conductive member 40 does not necessarily contribute to electrical conduction in the through hole 20. That is, the electrically-conductive member 40 can function as a heat dissipation member.

The solid particle 30 is provided in the through hole 20. In the first embodiment, one solid particle 30 is provided in one through hole 20. The solid particle 30 includes, for example, at least one material selected from the group consisting of diamond, silicon carbide (SiC), boron nitride (BN), nanocarbon, copper (Cu), and silver (Ag). Each of diamond and nanocarbon has a high thermal conductivity, and thus diamond and nanocarbon are preferable, for example. In the present embodiment, the solid particle 30 is diamond. The solid particle 30 can be artificially produced industrial diamond. Diamond has a higher hardness and a lower coefficient of thermal expansion (CTE) than those of metals used for substrates. The coefficient of thermal expansion of diamond is closer to the coefficient of thermal expansion of a ceramic than the coefficient of thermal expansion of a metal such as copper or silver. Therefore, by disposing diamond, which is the solid particle 30, in the electrically-conductive member 40, shrinkage and cracks due to heat are less likely to occur in the electrically-conductive member 40, and also cracks due to heat are less likely to occur in a ceramic. Further, diamond has a higher thermal conductivity than that of a metal and is isotropic in the thermal conduction direction. Thus, the heat dissipation of the base 10 can be improved by disposing diamond in the electrically-conductive member 40. The shape of the solid particle 30 is, for example, a sphere or a polyhedron, and can be a polyhedron close to a sphere. For example, an equivalent spherical diameter D (in other words, a particle diameter D) of the solid particle 30 is larger than the second opening diameter X2, is smaller than the first opening diameter X1, and is smaller than the thickness t of the base 10. For example, the equivalent spherical diameter D of the solid particle 30 is 50 μm or more and 500 μm or less. The diameter of the largest imaginary sphere included in the solid particle 30 is preferably larger than the second opening diameter X2, and the diameter of the smallest imaginary sphere surrounding the solid particle 30 is preferably smaller than the first opening diameter X1. In the present specification, when the smallest sphere that circumscribes diamond D is assumed, the term “equivalent spherical diameter (particle diameter)” refers to the diameter of the sphere.

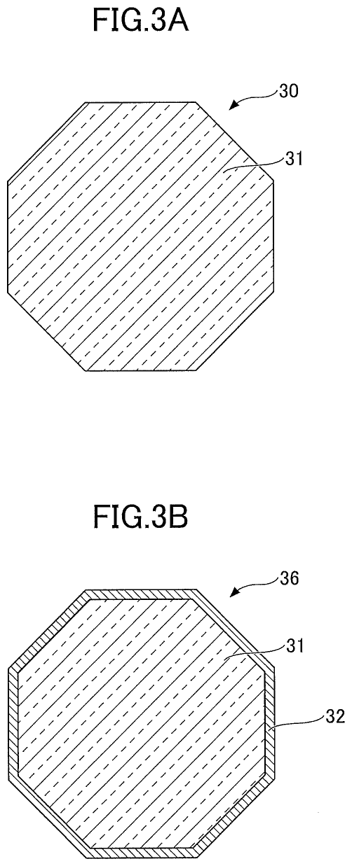

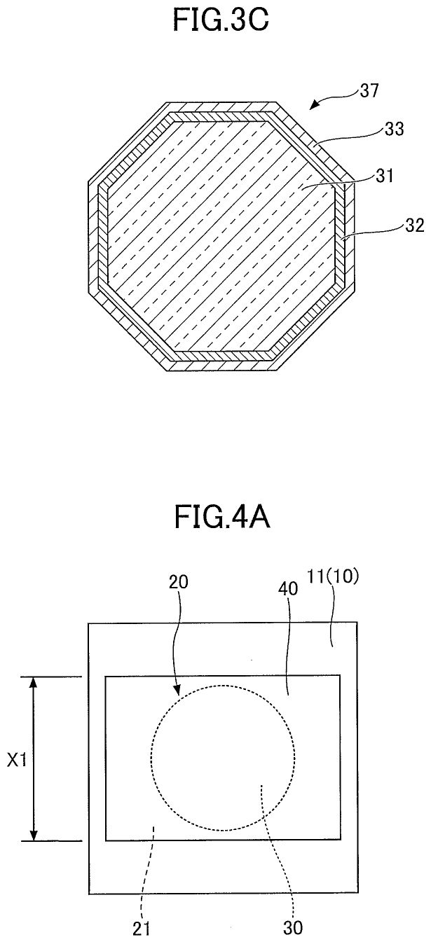

A configuration of the solid particle 30 will be described. FIG. 3A to FIG. 3C are cross-sectional views illustrating examples of the solid particle 30. In the example illustrated in FIG. 3A, the solid particle 30 is a diamond particle 31. The shape of the diamond particle 31 is, for example, a polyhedron having a cleaved surface. The solid particle 30 can be a composite particle including the diamond particle 31 and a plating layer covering the diamond particle 31. For example, as illustrated in FIG. 3B, the solid particle 30 can be a composite particle 36 including the diamond particle 31 and a nickel (Ni) plating layer 32 covering the diamond particle 31. Further, as illustrated in FIG. 3C, the solid particle 30 can be a composite particle 37 including the diamond particle 31, the nickel (Ni) plating layer 32 covering the diamond particle 31, and a copper (Cu) plating layer 33 covering the nickel plating layer. In particular, when the solid particle 30 includes the diamond particle 31, good heat conductivity can be obtained. If the solid particle 30 is a composite particle having a plating layer on the surface thereof, the thickness of the plating layer is very small relative to the volume of the diamond particle 31, and thus the thickness of the plating layer can be ignored.

The particle diameter D of the solid particle 30 is determined by image analysis of an observation photograph of a cross section, sieving, or the like. For example, in a scanning electron microscope energy dispersive X-ray spectroscopy (“SEM-EDX”, which can be hereinafter referred to as “EDX”), the diamond particle 31 is observed to be darker than copper or silver included in the electrically-conductive member 40. The particle diameter D of the solid particle 30 is obtained by extracting a region that appears black from an image, and measuring the size of the region. Alternatively, the solid particle 30 can be taken out by using an acid solution to dissolve a metal included in the electrically-conductive member 40. The particle diameter D of the solid particle 30 is obtained by observing the taken-out solid particle 30 with, for example, an optical microscope, a scanning electron microscope (SEM), or the SEM-EDX, and measuring the size of the taken-out solid particle 30. Alternatively, the taken-out solid particle 30 can be sieved through a mesh. The solid particle 30 is sequentially sieved through a fine mesh and then a coarse mesh. The particle diameter D of the solid particle 30 can be estimated from the opening size of a mesh through which the solid particle 30 has passed.

The volume of the solid particle 30 is preferably 25% or more, more preferably 30% or more, and still more preferably 35% or more of the volume of the through hole 20. As the proportion of the solid particle 30 in the through hole 20 increases, better heat dissipation can be obtained. The proportion of the solid particle 30 in the through hole 20 is preferably determined in consideration of heat dissipation and electrical conductivity.

In the ceramic substrate 1, the electrically-conductive member 40 and the solid particle 30 are disposed in the through hole 20, and the thermal conductivity of the solid particle 30 is higher than the thermal conductivity of the electrically-conductive member 40. Therefore, the thermal conductivity can be improved as compared to when the solid particle 30 is not disposed in the through hole 20. That is, the ceramic substrate 1 can improve heat dissipation.

Further, the electrically-conductive member 40 is continuous between the first surface 11 and the second surface 12, and thus electrical conductivity can be secured between the surface on the first surface 11 side of the electrically-conductive member 40 and the surface on the second surface 12 side of the electrically-conductive member 40.

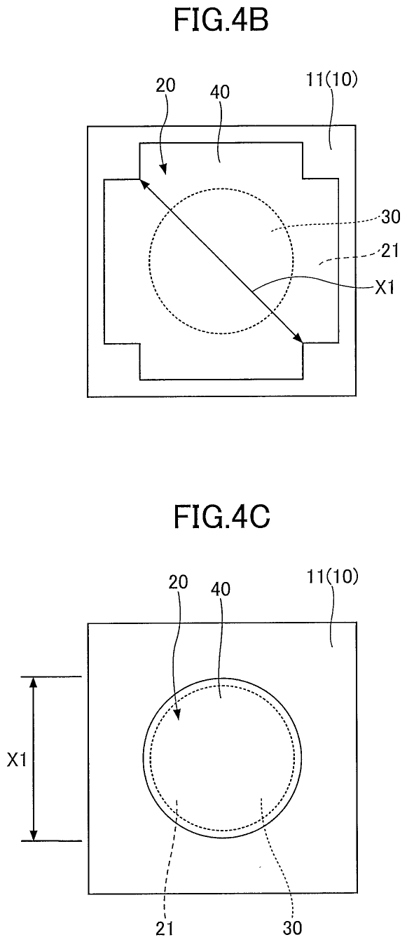

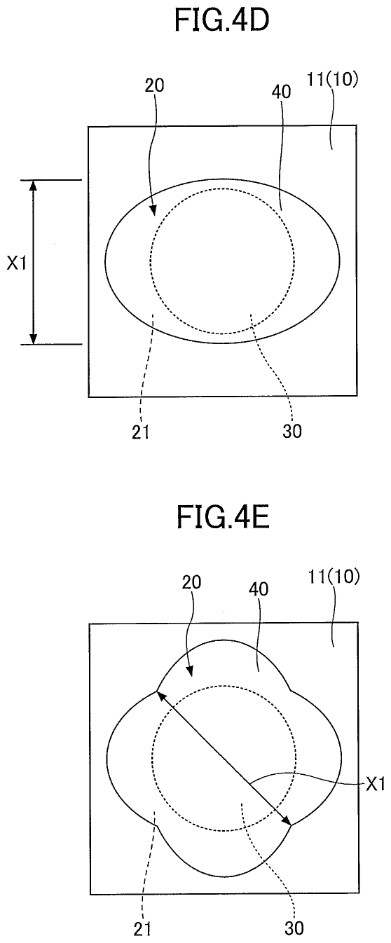

The shape of the inner lateral surfaces defining the through hole 20 in a plan view will be described. The shape of the inner lateral surfaces defining the through hole 20 in a plan view is not limited to a square shape. FIG. 4A to FIG. 4E are diagrams illustrating through holes 20 of the ceramic substrate 1 as viewed from the first surface 11 side of the base 10. As illustrated in FIG. 4A, the shape of inner lateral surfaces defining a through hole 20 in a plan view can be a rectangular shape (a rectangular shape other than a square shape) having long sides and short sides. In this case, the length of a short side at the first surface 11 corresponds to the first opening diameter X1, and the length of a short side at the second surface 12 corresponds to the second opening diameter X2. The length of a long side is 1.5 times or more and 2.0 times or less the length of a short side.

As illustrated in FIG. 4B, the shape of inner lateral surfaces defining a through hole 20 in a plan view can be a cross shape. Specifically, the shape of inner lateral surfaces defining a through hole 20 in a plan view is a shape in which two rectangles overlap each other such that long sides of one of the rectangles intersect long sides of the other rectangle. The angle of intersection at this time is, for example, 90°. In this case, the distance between the two most distant intersections, among four intersections at which the two rectangles overlap each other, at the first surface 11 corresponds to the first opening diameter X1, and the distance between the two most distant intersections at the second surface 12 corresponds to the second opening diameter X2. The length of a long side of each of the rectangles is 1.5 times or more and 2.0 times or less the length of a short side of each of the rectangles.

As illustrated in FIG. 4C, the shape of inner lateral surfaces defining a through hole 20 in a plan view can be a circular shape. In this case, the diameter on the first surface 11 side of the through hole 20 corresponds to the first opening diameter X1, and the diameter on the second surface 12 side of the through hole 20 corresponds to the second opening diameter X2. When the shape of the inner lateral surfaces defining the through hole 20 in a plan view is a circular shape, the solid particle 30 preferably has, instead of a spherical shape, a shape such as a polyhedron such that a gap is formed between the solid particle 30 and the inner lateral surfaces 21. This allows the electrically-conductive paste 41 to be easily flow to the second surface 12 side relative to the solid particle 30.

As illustrated in FIG. 4D, the shape of inner lateral surfaces defining a through hole 20 in a plan view can be an elliptical shape. In the example illustrated in FIG. 4D, the minor axis on the first surface 11 side of the through hole 20 corresponds to the first opening diameter X1, and the minor axis on the second surface 12 side of the through hole 20 corresponds to the second opening diameter X2. The length of a major axis is 1.5 times or more and 2.0 times or less the length of a minor axis.

As illustrated in FIG. 4E, the shape of inner lateral surfaces defining a through hole 20 can be a shape in which two ellipses overlap each other such that the major axis of one of the ellipses intersects the major axis of the other ellipse. The angle of intersection at this time is, for example, 90°. In this case, the distance between the two most distant intersections, among four intersections at which the two ellipses overlap each other, at the first surface 11 corresponds to the first opening diameter X1, and the distance between the two most distant intersections at the second surface 12 corresponds to the second opening diameter X2. The length of a major axis of each of the ellipses is 1.5 times or more and 2.0 times or less the length of a minor axis of each of the ellipses.

In order to compare the size of the first opening diameter X1 and the size of the second opening diameter X2, the equivalent circle diameter of the opening shape on the first surface 11 side of the through hole 20 can be used as the first opening diameter X1, and the equivalent circle diameter of the opening shape on the second surface 12 side of the through hole 20 can be used as the second opening diameter X2.

The thickness t of the base 10, the first opening diameter X1, the second opening diameter X2, and the equivalent spherical diameter D of the solid particle 30 are not particularly limited. Table 1 indicates example values of the thickness t of the base 10, the first opening diameter X1, the second opening diameter X2, and the equivalent spherical diameter D of the solid particle 30 in a case where the shape of the inner lateral surfaces defining the through hole 20 in a plan view is a square shape or a circular shape.

TABLE 1

| | FIRST | SECOND | EQUIVALENT |
|---|---|---|---|
| | OPENING | OPENING | SPHERICAL |
| THICKNESS t | DIAMETER | DIAMETER | DIAMETER D OF |
| OF BASE | X1 | X2 | SOLID PARTICLE |
| (μm) | (μm) | (μm) | (μm) |
| 320 | 270~290 | 203~250 | 250~275 |
| | 220~240 | 165~209 | 175~225 |
| | 170~190 | 128~165 | 150~175 |
| | 120~140 | 90~122 | 100~125 |
| 250 | 215~235 | 161~204 | 175~225 |
| | 165~180 | 124~157 | 150~175 |
| | 115~130 | 86~163 | 100~125 |
| 200 | 185~190 | 140~164 | 150~175 |
| | 160~170 | 120~148 | 125~150 |
| 150 | 135~140 | 100~122 | 125~135 |
| | 110~120 | 83~104 | 100~125 |
| 100 | 85~95 | 64~78 | 80~85 |

When dimensions indicated in Table 1 are adopted, the angle θ of the inclination of each of the inner lateral surfaces 21 with respect to the second surface 12 is preferably 83° or more and 86° or less.

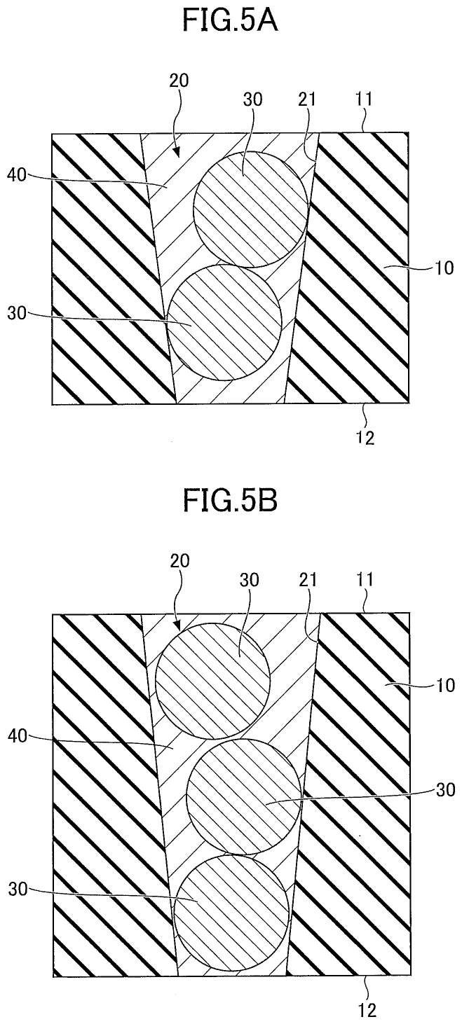

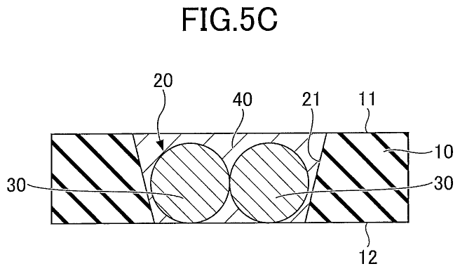

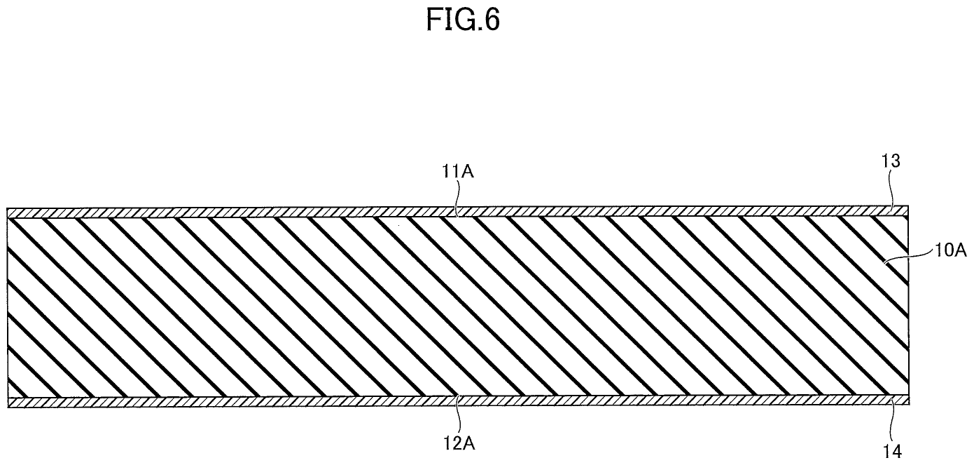

A plurality of solid particles 30 can be arranged in one through hole 20. As illustrated in FIG. 5A, two solid particles 30 can be arranged in one through hole 20. As illustrated in FIG. 5B, three solid particles 30 can be arranged in one through hole 20. If a plurality of solid particles 30 are arranged in one through hole 20, the plurality of solid particles 30 can be in direct contact with each other or the electrically-conductive member 40 can be present between the plurality of solid particles 30. Table 2 indicates example values of the thickness t of the base 10 and the equivalent spherical diameter D of each of two solid particles 30 in a case where the two solid particles 30 are arranged in one through hole 20. Table 3 indicates example values of the thickness t of the base 10 and the equivalent spherical diameter D of each of three solid particles 30 in a case where the three solid particles 30 are arranged in one through hole 20. However, the equivalent spherical diameters D of the solid particles 30 in Table 2 and Table 3 are not limited to the numerical values described in Table 2 and Table 3.

TABLE 2

| | EQUIVALENT |
|---|---|
| THICKNESS t | SPHERICAL DIAMETER D |
| OF BASE | OF SOLID PARTICLE |
| (μm) | (μm) |
| 1000 | 300 |
| 500 | 250 |
| | 200 |
| 320 | 150 |
| | 100 |
| 250 | 100 |

TABLE 3

| | EQUIVALENT |
|---|---|
| THICKNESS t | SPHERICAL DIAMETER D |
| OF BASE | OF SOLID PARTICLE |
| (μm) | (μm) |
| 1000 | 300 |
| 500 | 150 |
| 320 | 100 |

In the examples illustrated in FIG. 5A and FIG. 5B, a plurality of solid particles 30 overlap each other in the depth direction of a through hole 20. As illustrated in FIG. 5C, a plurality of solid particles 30 can be arranged side by side in a direction perpendicular to the depth direction of a through hole 20 without overlapping each other in the depth direction of the through hole 20. Further, as illustrated in FIG. 5C, a portion of the solid particles 30 is not necessarily covered by the electrically-conductive member 40 and can be exposed from the electrically-conductive member 40 at either the first surface 11 or the second surface 12 or at both the first surface 11 and the second surface 12. In the examples illustrated in FIG. 5A to FIG. 5C, the shape of inner lateral surfaces defining each of the through holes 20 in a plan view is a square shape or a circular shape.

Next, a method of manufacturing the ceramic substrate 1 according to the first embodiment will be described. FIG. 6 to FIG. 12 are cross-sectional views illustrating the method of manufacturing the ceramic substrate 1 according to the first embodiment.

The method of manufacturing the ceramic substrate 1 according to the first embodiment includes a step of a preparing a base having a through hole, a step of disposing one or more solid particles in the through hole, a step of disposing an electrically-conductive paste in the through hole after the step of disposing the one or more solid particles in the through hole, and a step of forming an electrically-conductive member by sintering the electrically-conductive paste.

In the step of preparing a base having a through hole, a base 10 having a first surface 11, a second surface 12 opposite to the first surface 11, and a through hole 20 having a first opening diameter X1 at the first surface 11 and a second opening diameter X2 at the second surface 12 is prepared. The first opening diameter X1 is larger than the second opening diameter X2.

Specifically, as illustrated in FIG. 6, a ceramic base 10A, which serves as the base 10, is prepared. The ceramic is, for example, silicon nitride (Si₃N₄) or aluminum nitride (AlN). The base 10A has a first surface 11A, which serves as the first surface 11, and a second surface 12A, which serves as the second surface 12. If an electrically-conductive paste, which will be described later, shrinks upon curing, a first film 13 is preferably attached to the first surface 11A and a second film 14 is preferably attached to the second surface 12A as illustrated in FIG. 6.

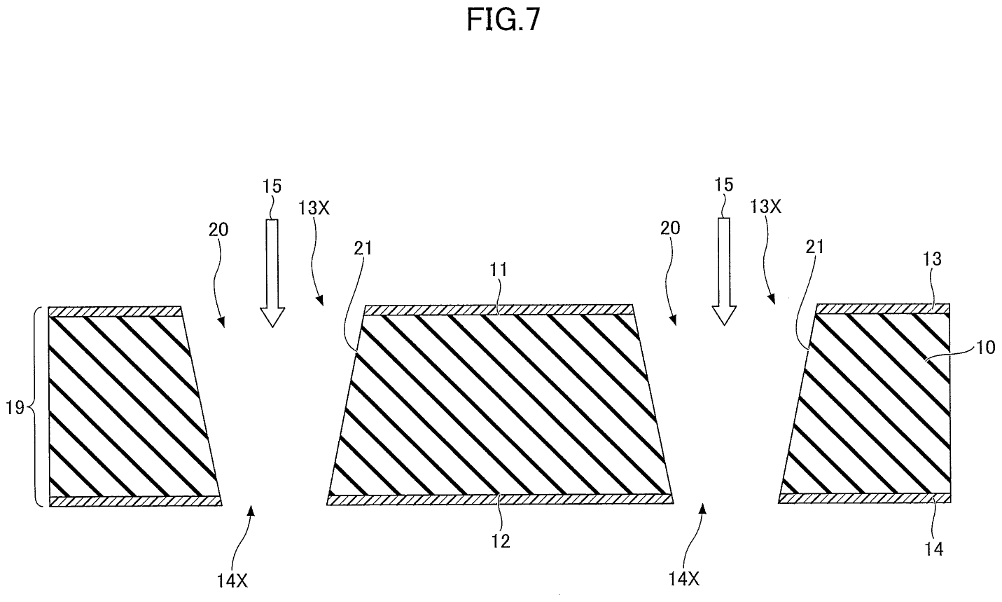

Next, as illustrated in FIG. 7, by irradiating the base 10A with laser light 15 from the first film 13 side, a first opening 13X is formed in the first film 13, a through hole 20 having a first opening diameter X1 and a second opening diameter X2 is formed in the base 10A, and a second opening 14X is formed in the second film 14. The first opening diameter X1 is larger than the second opening diameter X2. The laser light 15 is, for example, CO₂ laser light or YAG laser light. In the present embodiment, the through hole 20 is formed by irradiating the base 10A with CO₂ laser light having a wavelength of 9.4 m and a maximum power of 715 W. As a result, in the first film 13 attached to the first surface 11A, the first opening 13X is formed at a position overlapping the through hole 20, and in the second film 14 attached to the second surface 12A, the second opening 14X of is formed at a position overlapping the through hole 20. Accordingly, a stack of the first film 13, the base 10, and the second film 14 is prepared as a film-attached base 19. The base 10A serves as the base 10 having the first surface 11, the second surface 12, and the through hole 20.

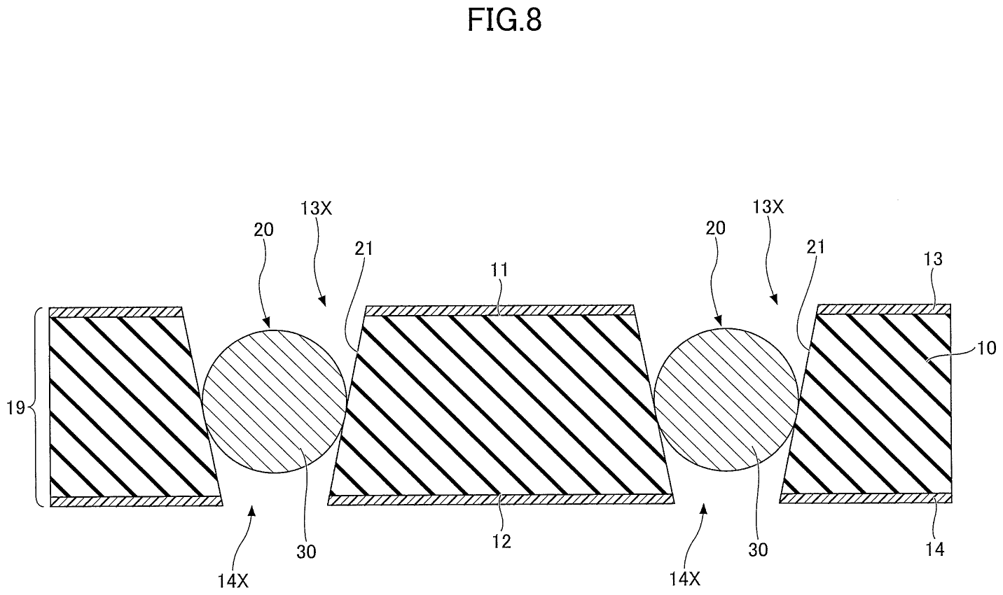

In the step of providing one or more solid particles in the through hole, one or more solid particles 30 are provided in the through hole 20 from the first surface 11 side as illustrated in FIG. 8. By setting the second opening diameter X2 to be smaller than the equivalent spherical diameter D of the one or more solid particles 30, the one or more solid particles 30 can be prevented from passing through the through hole 20 by being sandwiched between the inner lateral surfaces 21, and thus the one or more solid particles 30 remain in the through hole 20. When the diameter of the largest imaginary sphere included in each of the one or more solid particles 30 is larger than the second opening diameter X2, the one or more solid particles 30 can easily remain in the through hole 20.

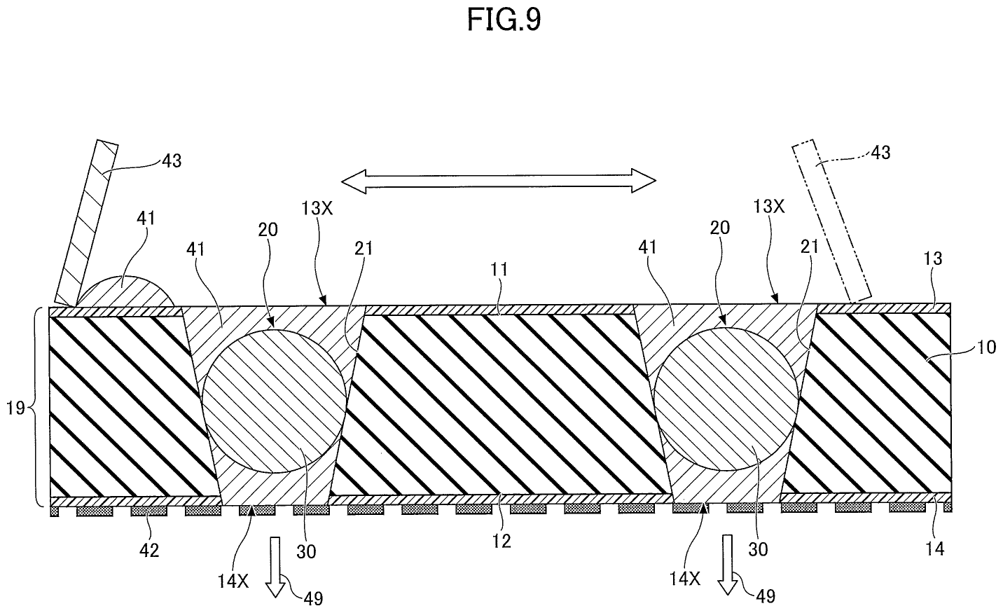

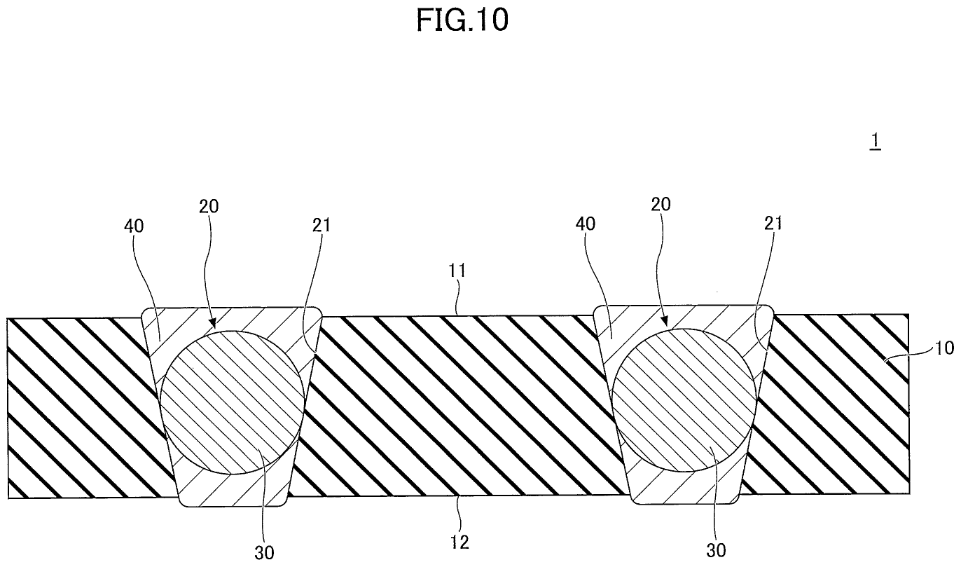

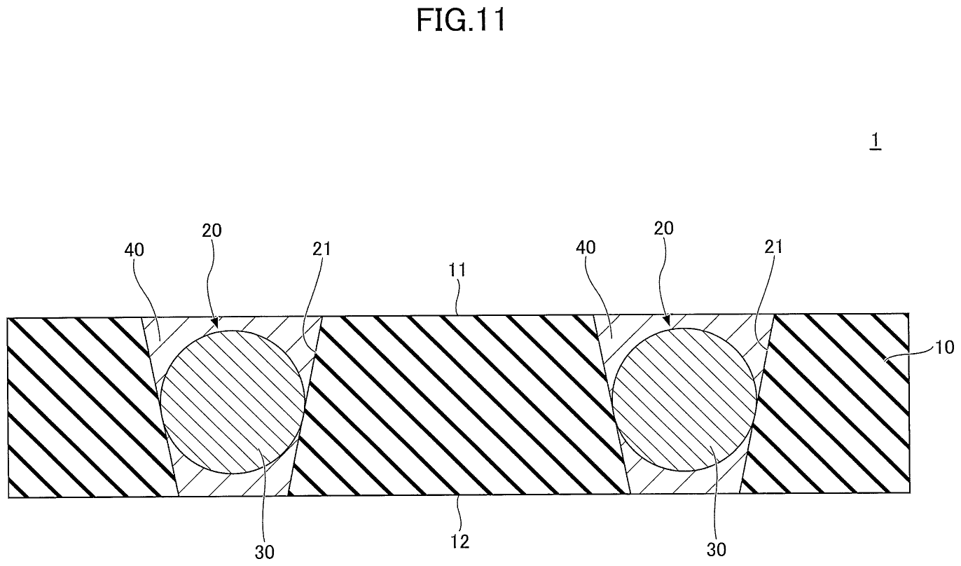

In the step of disposing an electrically-conductive paste in the through hole after the step of disposing the one or more solid particles in the through hole, an adsorbent paper 42 is disposed in contact with the second film 14, and an electrically-conductive paste 41 is disposed in the through hole 20 by using a squeegee 43 while performing suction from the second film 14 side as illustrated in FIG. 9. The adsorbent paper 42 is a member having large spacing between paper fibers and allowing air to easily pass therethrough, and is, for example, a metal laminated paper. By performing suction (hereinafter can be referred to as “suction 49”) in a direction indicted by an arrow 49, the one or more solid particles 30 can be efficiently disposed in the through holes 20. The electrically-conductive paste 41 is, for example, a copper paste or a silver paste. The copper paste or the silver paste can include an activated metal. The electrically-conductive paste 41 is preferably continuous between the first surface 11 and the second surface 12 in the through hole 20. The through hole 20 in which the one or more solid particles 30 are disposed can be filled with the electrically-conductive paste 41. In this manner, the electrically-conductive paste 41 is disposed in the through hole 20. The electrically-conductive paste 41 can also be disposed in the first opening 13X and the second opening 14X.

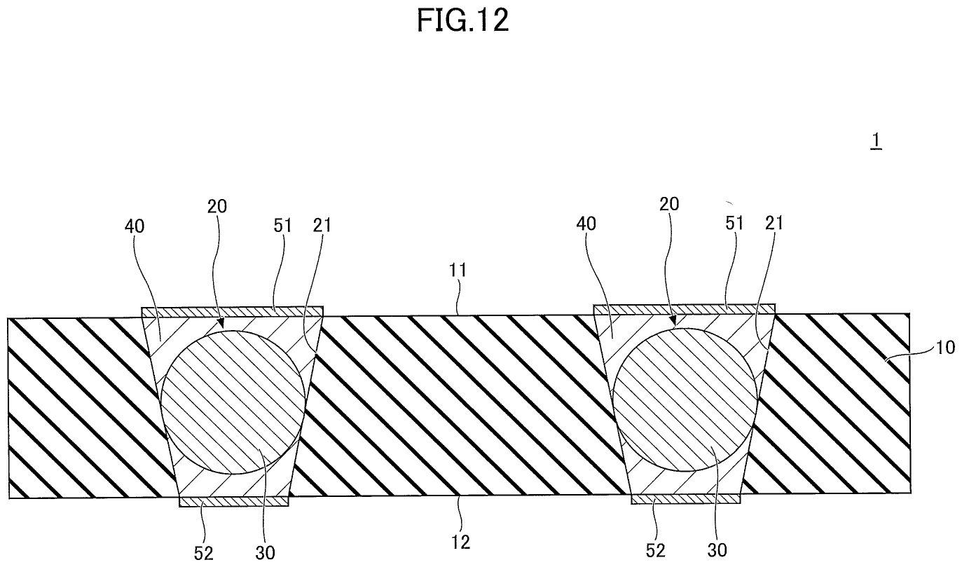

Before the step of forming an electrically-conductive member, a step of peeling off the first film 13 and the second film 14 from the base 10 can be performed as illustrated in FIG. 10. By peeling off the first film 13 and the second film 14 from the base 10, the electrically-conductive paste 41 protruding relative to the first surface 11 by the thickness of the first film 13 and protruding relative to the second surface 12 by the thickness of the second film 14, that is, the electrically-conductive paste 41 whose lateral surfaces are partially exposed is obtained.

In the step of forming an electrically-conductive member by sintering the electrically-conductive paste, an electrically-conductive member 40 that is continuous between the first surface 11 and the second surface 12 is formed by sintering the electrically-conductive paste 41 at a temperature of 150° C. or more and 900° C. or less for 0.5 hours or more and 3 hours or less.

In this manner, the ceramic substrate 1 according to the first embodiment can be manufactured.

After the electrically-conductive member 40 is formed, a grinding process or a polishing process for removing a portion of the electrically-conductive member 40 protruding relative to the first surface 11 is performed as illustrated in FIG. 11. In addition, a grinding process or a polishing process for removing a portion of the electrically-conductive member 40 protruding relative to the second surface 12 is performed. Further, as illustrated in FIG. 12, metal layers can be formed on the electrically-conductive member 40 exposed at the first surface 11 and the second surface 12 by performing surface treatment such as plating. In the example illustrated in FIG. 12, a first connection pad 51, which is a metal layer, is formed on the surface on the first surface 11 side of the electrically-conductive member 40, and a second connection pad 52, which is a metal layer, is formed on the surface on the second surface 12 side of the electrically-conductive member 40. Each of the first connection pad 51 and the second connection pad 52 includes, for example, nickel, palladium, titanium, ruthenium, gold, or the like.

When the electrically-conductive paste 41 is disposed in the through hole 20, the volume of the electrically-conductive paste 41 is larger than the volume of the through hole 20 by the thicknesses of the first film 13 and the second film 14, and thus the electrically-conductive paste 41 overflows from the first surface 11 and the second surface 12 before being sintered. Therefore, even if the volume of the electrically-conductive member 40 becomes smaller than the volume of the electrically-conductive paste 41 accompanying the sintering, a recess portion recessed relative to the first surface 11 or the second surface 12 is unlikely to be formed in the surface of the electrically-conductive member 40.

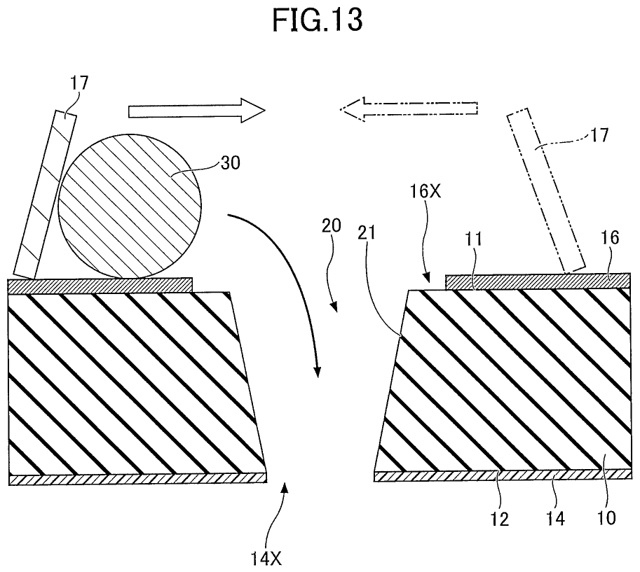

In the step of disposing one or more solid particles in the through hole, a metal mask can be used when one or more solid particles 30 are disposed in the through hole 20. FIG. 13 is a cross-sectional view illustrating an example of a method of disposing a solid particle 30 in the through hole 20.

In this example, as illustrated in FIG. 13, a metal mask 16 having an opening 16X is disposed on the first surface 11 of the base 10. The opening 16X of the metal mask 16 has a larger opening diameter than the first opening diameter X1 on the first surface 11 side of the through hole 20, and the through hole 20 and the second opening 14X are located inward of the opening 16X in a plan view perpendicular to the first surface 11.

Next, one solid particle 30 is disposed in the through hole 20 by using a squeegee 17. In the present embodiment, the squeegee 17 reciprocates on the metal mask 16, and thus the solid particle 30 is disposed in the through hole 20 in the outward path, and a surplus of the solid particle 30 in the through hole 20 and around the through hole 20 is removed in the return path. Thereafter, the metal mask 16 can be removed from the first surface 11 of the base 10.

Alternatively, a liquid in which a plurality of solid particles 30 are dispersed can be applied from the metal mask 16 side by, for example, spraying, such that the plurality of solid particles 30 are disposed in the through hole 20. The liquid volatilizes in the step of forming the electrically-conductive member by sintering the electrically-conductive paste. Alternatively, a large number of solid particles 30 can be blown toward the metal mask 16 by using a gas such as air, such that the large number of solid particles 30 are disposed in the through hole 20.

By performing a method as described above, a solid particle 30 can be disposed in the through hole 20. By using the metal mask 16 to dispose the solid particle 30 in the through hole 20, the base 10 can be prevented from being damaged by cracking or chipping due to collision of the solid particle 30 with the first surface 11 of the base 10.

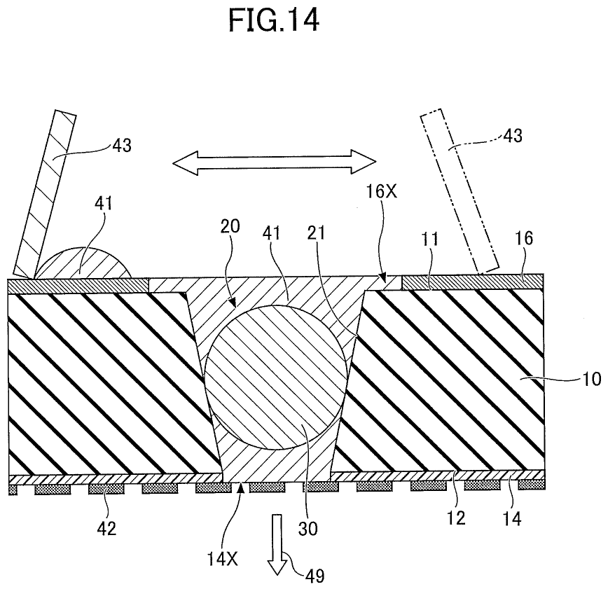

In the step of disposing the electrically-conductive paste in the through hole after the step of disposing the one or more solid particles in the through hole, when the electrically-conductive paste 41 is disposed in the through hole 20, the metal mask 16 can be used as described above, and further the adsorbent paper 42 can be used. FIG. 14 is a cross-sectional view illustrating another example of a method of disposing the electrically-conductive paste 41.

In this example, the adsorbent paper 42 is disposed on the second film 14 so as to overlap the through hole 20 and the second opening 14X in a plan view.

Next, while performing suction 49 from the second film 14 side, the electrically-conductive paste 41 is disposed in the through hole 20 and the second opening 14X by using the squeegee 43. By performing the suction 49, a solid particle 30 is drawn into the through hole 20, and thus the solid particle 30 can be efficiently disposed in the through hole 20. Further, the adsorbent paper 42 can prevent the electrically-conductive paste 41 from leaking from the through hole 20 and the second opening 14X. In this example, the opening 16X of the metal mask 16 can be filled with the electrically-conductive paste 41. Next, the metal mask 16 and the second film 14 are peeled off from the base 10.

When the first film 13, the second film 14, and the metal mask 16 are peeled off from the base 10, it is preferable that the electrically-conductive paste 41 disposed in the through hole 20 does not adhere to the peeled first film 13, the peeled second film 14, and the peeled metal mask 16 as much as possible. For example, it is desirable that the first film 13 is slowly peeled off at a nearly horizontal angle relative to the first surface 11 of the base 10. Further, for example, it is desirable that the second film 14 is slowly peeled off at a nearly horizontal angle relative to the second surface 12 of the base 10.

By performing a method as described above, the electrically-conductive paste 41 can be disposed in the through hole 20.

### Second Embodiment

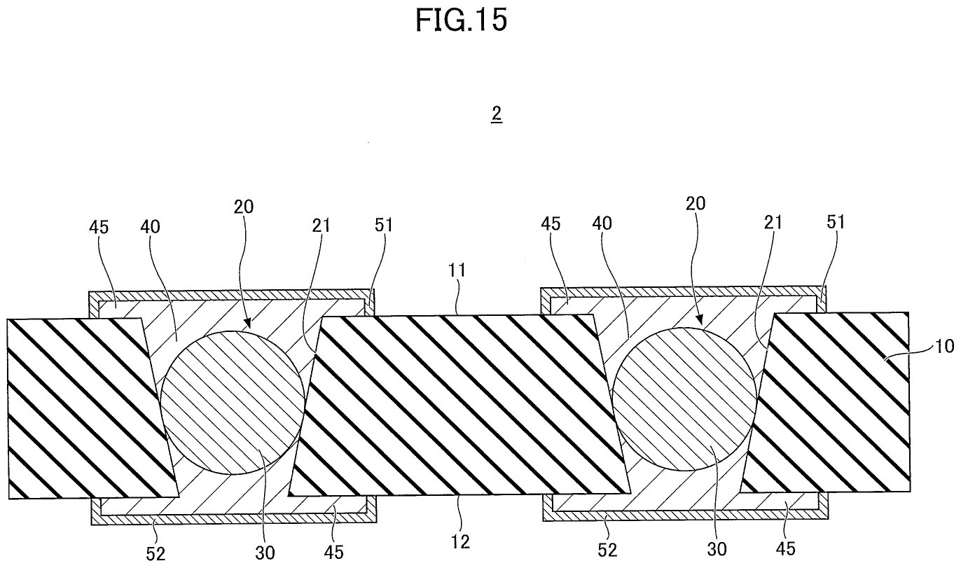

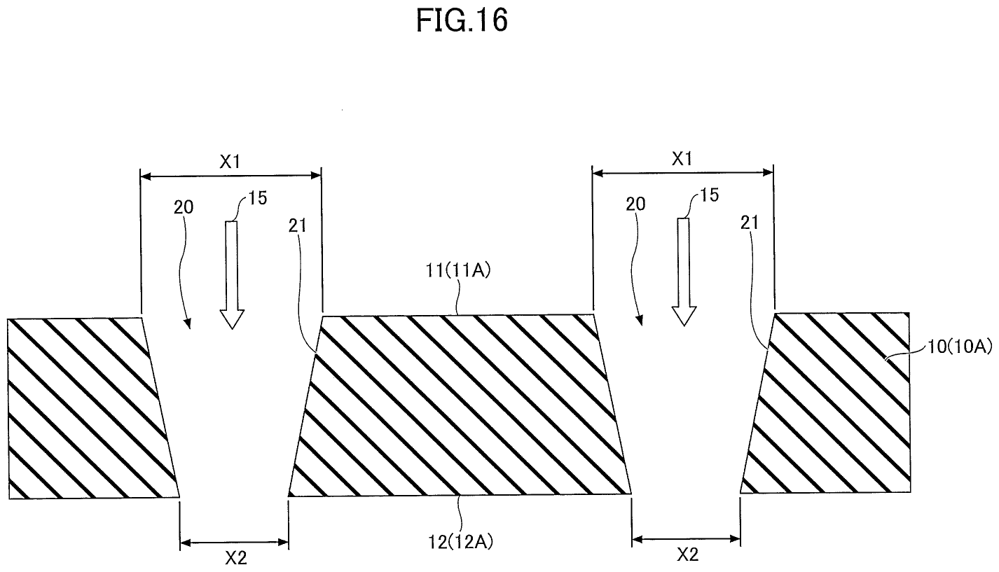

A second embodiment will be described. FIG. 15 is a cross-sectional view illustrating a ceramic substrate according to the second embodiment. The second embodiment differs from the first embodiment in that an electrically-conductive member 40 protrudes relative to the first surface 11 and the second surface 12 of the base 10.

As illustrated in FIG. 15, a ceramic substrate 2 according to the second embodiment includes a first connection pad 51 and a second connection pad 52 on the surfaces of the electrically-conductive member 40 protruding relative to the first surface 11 and the second surface 12 of the base 10. The electrically-conductive member 40 is composed of a sintered body 45, and the sintered body 45 includes a portion close to the first surface 11 of the base 10 and a portion close to the second surface 12 of the base 10.

The first connection pad 51 is provided on the first surface 11, contacts the electrically-conductive member 40, and is electrically connected to the electrically-conductive member 40. The second connection pad 52 is provided on the second surface 12, contacts the electrically-conductive member 40, and is electrically connected to the electrically-conductive member 40. Each of the first connection pad 51 and the second connection pad 52 includes, for example, nickel, palladium, titanium, ruthenium, gold, or the like.

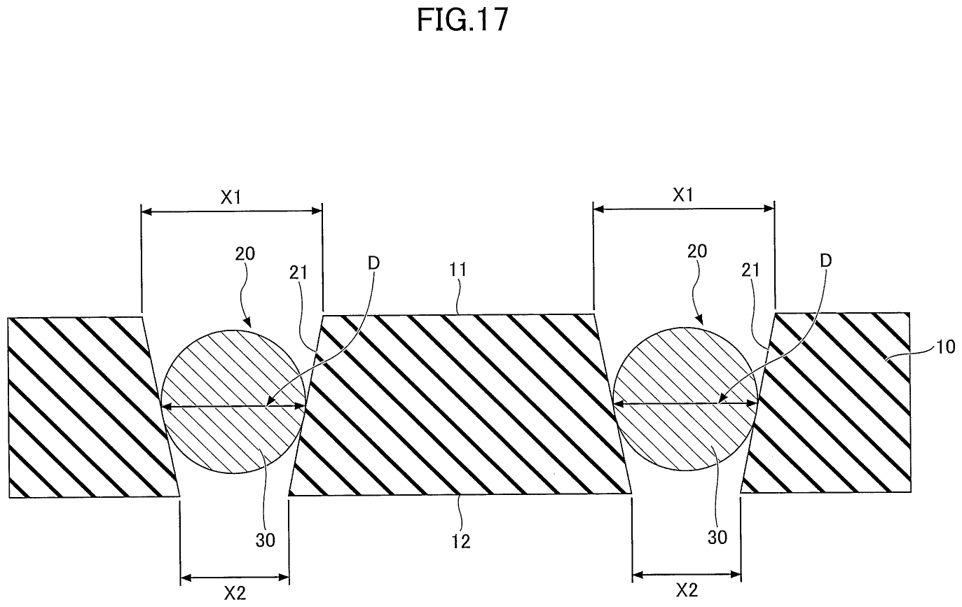

Next, a method of manufacturing the ceramic substrate 2 according to the second embodiment will be described. FIG. 16 to FIG. 20 are cross-sectional views illustrating the method of manufacturing the ceramic substrate 2 according to the second embodiment.

First, as illustrated in FIG. 16, a base 10A, which serves as the base 10, is prepared. The base 10A has a first surface 11A, which serves as the first surface 11, and a second surface 12A, which serves as the second surface 12. Next, without a first film 13 and a second film 14 being attached to the first surface and the second surface, the base 10A is irradiated with laser light 15 from the first surface 11A side, thereby forming a through hole 20 penetrating between the first surface 11A and the second surface 12A of the base 10A and having a first opening diameter X1 at the first surface 11 and a second opening diameter X2 at the second surface 12. The first opening diameter X1 on the first surface 11 side of the through hole 20 is larger than the second opening diameter X2 on the second surface 12 side of the through hole 20. As a result, the base 10 having the first surface 11 and the second surface 12 is prepared from the base 10A. Such a base 10 can be purchased.

Next, as illustrated in FIG. 17, one solid particle 30 is disposed in the through hole 20 from the first surface 11 side.

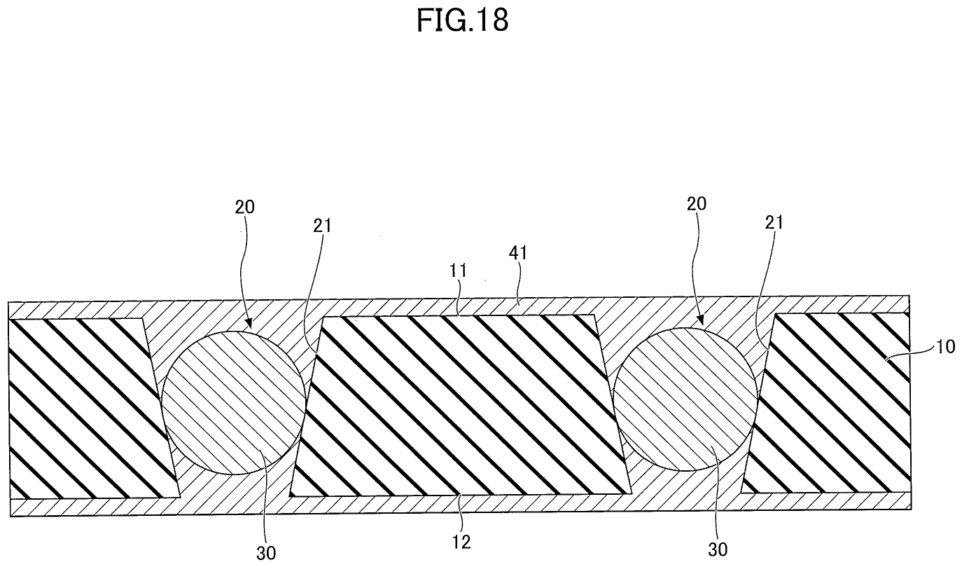

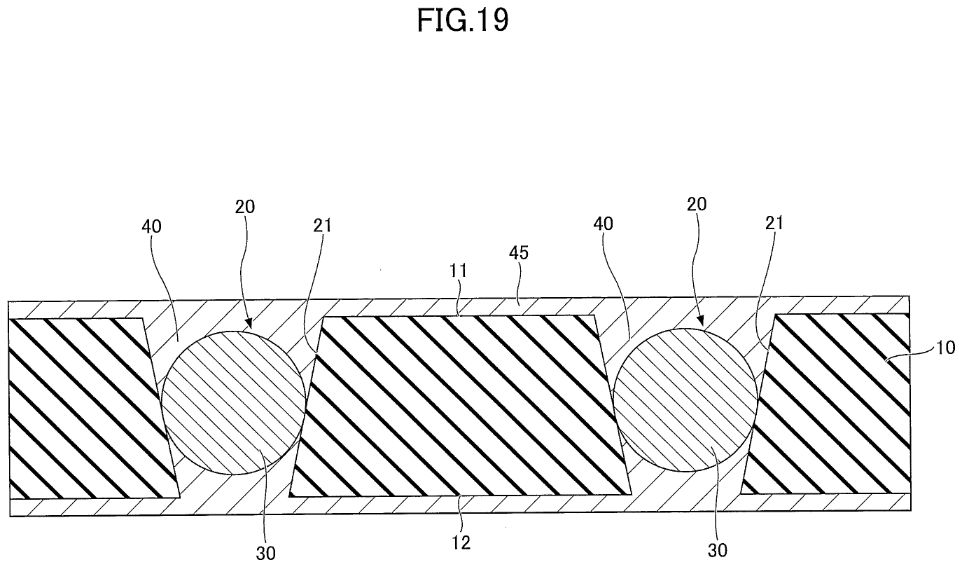

Next, as illustrated in FIG. 18, an electrically-conductive paste 41 is disposed in the through hole 20, and is also disposed on the first surface 11 and the second surface 12. In the present embodiment, the electrically-conductive paste 41 is printed on the first surface 11, the base 10 is inverted, and the electrically-conductive paste 41 is printed on the second surface 12. Specifically, before the electrically-conductive paste 41 is disposed in the through hole 20 and on the first surface 11, a first adsorbent paper is disposed on the second surface 12. Then, the electrically-conductive paste 41 is disposed in the through hole 20 and on the first surface 11 by printing the electrically-conductive paste 41 from the first surface 11 side. Then, a second adsorbent paper is disposed on the first surface 11 side of the electrically-conductive paste 41, and the base 10 is inverted. Next, the first adsorbent paper is peeled off from the second surface 12, and the electrically-conductive paste 41 is disposed in the through hole 20 and on the second surface 12 by printing the electrically-conductive paste 41 from the second surface 12 side. Thereafter, the second adsorbent paper is peeled off from the first surface 11 side of the electrically-conductive paste 41. The first adsorbent paper and the second adsorbent paper can be used as described above; however, after the electrically-conductive paste 41 is printed on the first surface 11, the electrically-conductive paste 41 can be semi-dried at a temperature of 80° C. or more and 100° C. or less for 1 minute or more and 3 minutes or less before the base 10 is inverted. In this case, the second adsorbent paper is not necessarily used.

In this manner, when the base 10 is inverted, the solid particle 30 disposed in the through hole 20 can be prevented from falling off from the through hole 20 or from changing its position by being moved in the through hole 20.

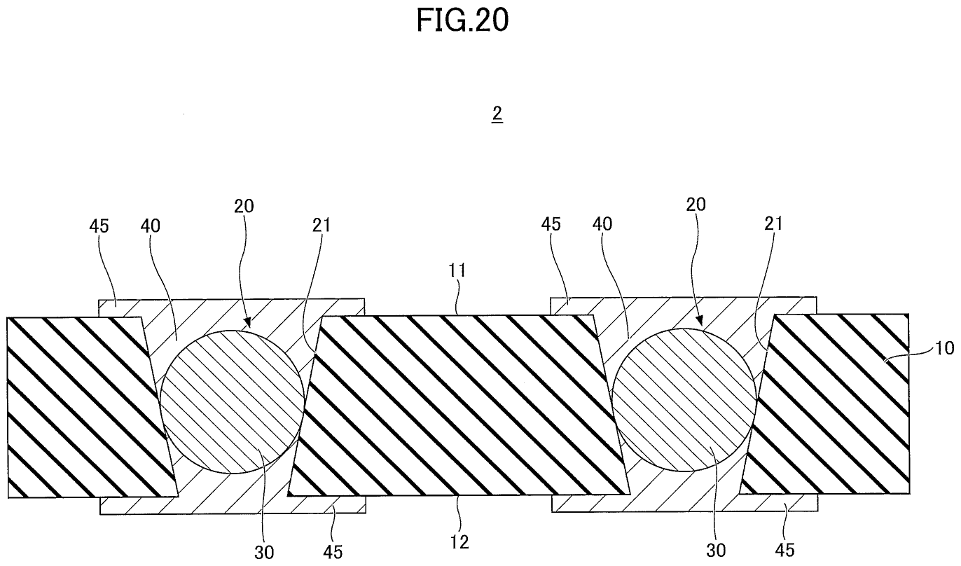

Next, as illustrated in FIG. 19, a sintered body 45 including an electrically-conductive member 40 is obtained by sintering the electrically-conductive paste 41 at a temperature of 150° C. or more and 900° C. or less for 0.5 hours or more and 3 hours or less. Thereafter, as illustrated in FIG. 20, at least one of at least a portion of the surface on the first surface 11 side of the sintered body 45 or at least a portion of the surface on the second surface 12 side of the sintered body 45 is removed by laser processing, etching, and the like, such that a desired wiring pattern is formed. In the etching, wet etching is preferable from the viewpoint of processing efficiency and accuracy. Portions of the sintered body 45 covering the first surface 11 and the second surface 12 can be removed by grinding, lapping, or the like.

Next, the first connection pad 51 is disposed on at least a portion of the surface of the electrically-conductive member 40 that protrudes relative to the first surface 11 of the base 10, and the second connection pad 52 is disposed on a portion of the surface of the electrically-conductive member 40 that protrudes relative to the second surface 12 of the base 10. Each of the first connection pad 51 and the second connection pad 52 is a metal layer including, for example, nickel, palladium, titanium, ruthenium, gold, or the like, and can be formed by plating.

In this manner, the ceramic substrate 2 according to the second embodiment illustrated in FIG. 15 can be manufactured.

The second embodiment can obtain the same effects as those of the first embodiment.

### Third Embodiment

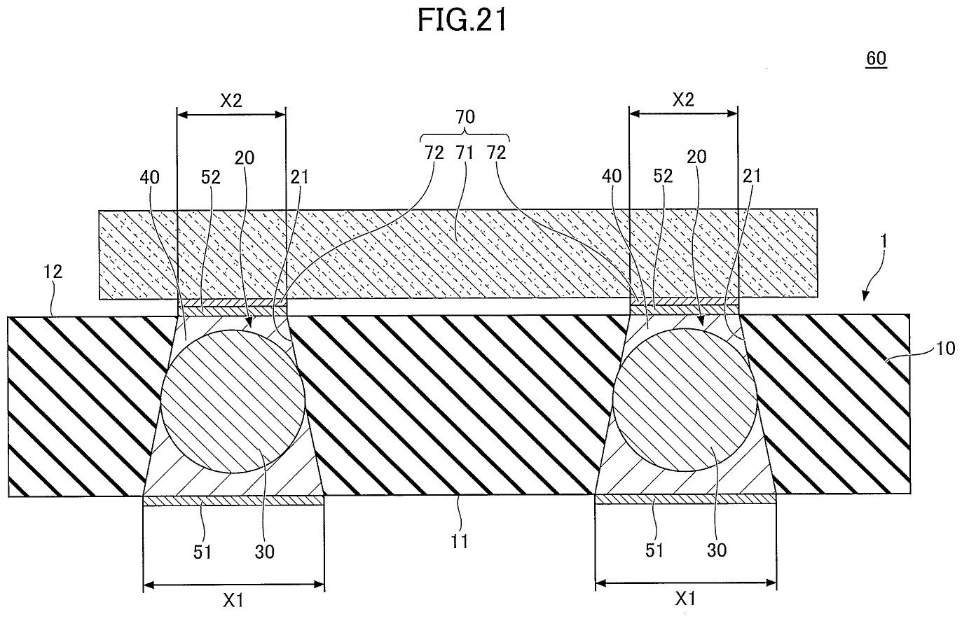

A third embodiment will be described. The third embodiment relates to a light source device. FIG. 21 is a cross-sectional view illustrating the light source device according to the third embodiment.

As illustrated in FIG. 21, a light source device 60 according to the third embodiment includes the ceramic substrate 1 according to the first embodiment and a light-emitting element 70.

The light-emitting element 70 is disposed on the second surface 12. The light-emitting element 70 includes an element body 71 including a semiconductor, and at least a pair of positive and negative element electrodes 72. The element electrodes 72 are provided on the lower surface of the element body 71. In the present embodiment, the light-emitting element 70 is mounted on second connection pads 52 of the ceramic substrate 1 such that the surface of the element body 71 on which the element electrodes 72 are provided (that is, the lower surface of the element body 71) faces the second surface 12. It is preferable that one element electrode 72 of the light-emitting element 70 is disposed on one second connection pad 52 of the ceramic substrate 1. Further, the element electrodes 72 are electrically connected to electrically-conductive members 40 of the ceramic substrate 1.

In the light-emitting element 70, the semiconductor included in the element body 71 is preferably made of various semiconductors such as group III-V compound semiconductors and group II-VI compound semiconductors. As the semiconductor, nitride-based semiconductors such as In_{X}Al_{Y}Ga_{1-X-Y}N (0≤X, 0≤Y, X+Y≤1) are preferably used, and InN, AlN, GaN, InGaN, AlGaN, InGaAlN, and the like can also be used. The light-emitting element 70 is, for example, a light-emitting diode (LED) or a laser diode (LD). The emission peak wavelength of the light-emitting element 70 is preferably 400 nm or more and 530 nm or less, more preferably 420 nm or more and 490 nm or less, and even more preferably 450 nm or more and 475 nm or less, from the viewpoint of light emission efficiency, excitation of a wavelength conversion substance, which will be described later, a color mixing relationship with the light emission thereof, and the like.

In the light source device 60, a portion of heat generated in the light-emitting element 70 is transmitted to the surface on the second surface 12 side of an electrically-conductive member 40, and is transmitted to the surface on the first surface 11 side of the electrically-conductive member 40 via the electrically-conductive member 40 and a solid particle 30. Then, the heat is released from the surface of on the first surface 11 side of the electrically-conductive member 40 to the outside. In the present embodiment, the cross-sectional area of the electrically-conductive member 40 increases as the distance from the light-emitting element 70 increases in the thickness direction of the base 10. Therefore, by disposing the light-emitting element 70 on the second surface 12 of the ceramic substrate 1, the heat generated in the light-emitting element 70 spreads from the end portion on the second surface 12 side of the through hole 20 having the second opening diameter X2 toward the end portion on the first surface 11 side of the through hole 20 having the first opening diameter X1 that is larger than the second opening diameter X2. That is, a path of the heat generated in the light-emitting element 70 and released to the outside through the electrically-conductive member 40 and the solid particle 30 in the through hole 20 is widened, and thus heat dissipation can be improved.

The light-emitting element 70 can be disposed on the first surface 11. Regardless of whether the light-emitting element 70 is disposed on the first surface 11 or the second surface 12, heat dissipation can be improved by, for example, adjusting the sizes of the first opening diameter X1 and the second opening diameter X2 of the through hole 20, appropriately selecting the material of the electrically-conductive member 40, the type and the number of solid particles 30, and the like.

In the light source device 60, a light-transmissive member can be disposed on the light-emitting element 70. The light-transmissive member is a member having, for example, a substantially rectangular shape in a top view and covers the upper surface of the light-emitting element 70. The light-transmissive member can be formed by using a light-transmissive resin material or an inorganic material such as a ceramic or glass. As the resin material, a thermosetting resin such as a silicone resin, a silicone-modified resin, an epoxy resin, an epoxy-modified resin, or a phenol resin can be used. In particular, a silicone resin having high light resistance and heat resistance or a modified resin thereof is preferable. As used herein, the term “light-transmissive” means that 60% or more of light from the light-emitting element 70 is preferably transmitted. Further, a thermoplastic resin such as a polycarbonate resin, an acrylic resin, a methylpentene resin, or a polynorbornene resin can be used for the light-transmissive member. Further, the light-transmissive member can contain a light diffusing substance or a wavelength conversion substance that converts a wavelength of at least a portion of the light from the light-emitting element 70. For example, the light-transmissive member can be a resin material, a ceramic, glass, or the like containing a wavelength conversion substance, a sintered body of a wavelength conversion substance, or the like. Further, the light-transmissive member can be a multilayer member in which a resin layer containing a wavelength conversion substance or a light diffusing substance is disposed on at least one of the upper surface or the lower surface of a molded body made of a resin, a ceramic, glass, or the like.

Examples of a wavelength conversion substance contained in the light-transmissive member include yttrium aluminum garnet based phosphors (for example, (Y,Gd)₃(Al,Ga)₅O₁₂:Ce), lutetium aluminum garnet based phosphors (for example, Lu₃(Al,Ga)₅O₁₂:Ce), terbium aluminum garnet based phosphors (for example, Tb₃(Al,Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, Ca₈MgSi₄O₁₆Cl₂:Eu), silicate based phosphors (for example, (Ba,Sr,Ca,Mg)₂SiO₄:Eu), oxynitride based phosphors such as β-SiAlON based phosphors (for example, (Si,Al)₃(O,N)₄:Eu) and α-SiAlON based phosphors (for example, Ca(Si,Al)₁₂(O,N)₁₆:Eu), nitride based phosphors such as LSN based phosphors (for example, (La,Y)₃Si₆N₁₁:Ce), BSESN based phosphors (for example, (Ba,Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr,Ca)AlSiN₃:Eu), fluoride based phosphors such as KSF based phosphors (for example, K₂SiF₆:Mn), KSAF based phosphors (for example, K₂(Si₁₋ₓAlₓ)F₆₋ₓ:Mn, where x satisfies 0<x<1), and MGF based phosphors (for example, 3.5MgO·0.5MgF₂·GeO₂:Mn), quantum dots having a Perovskite structure (for example, (Cs,FA,MA)(Pb,Sn)(F,Cl,Br,I)₃, where FA and MA represent formamidinium and methylammonium, respectively), II-VI quantum dots (for example, CdSe), III-V quantum dots (for example, InP), and quantum dots having a chalcopyrite structure (for example, (Ag,Cu)(In,Ga)(S,Se)₂). The phosphors described above are particles. One of these wavelength conversion substances can be used alone, or two or more of these wavelength conversion substances can be used in combination.

The lateral surfaces of the light-emitting element 70 and the lateral surfaces of the light-transmissive member can be covered by a covering member. The covering member directly or indirectly covers the lateral surfaces of the light-emitting element 70 and the lateral surfaces of the light-transmissive member. The upper surface of the light-transmissive member is exposed through the covering member. In order to improve the light extraction efficiency, the covering member is preferably composed of a member having a high light reflectance. For example, a resin material containing a light reflective substance such as a white pigment can be used for the covering member.

Examples of the light reflective substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, silicon oxide, and the like. It is preferable to use one of the above substances alone or a combination of two or more of the above substances. Further, as the resin material, it is preferable to use a base material including a resin material whose main component is a thermosetting resin such as an epoxy resin, an epoxy-modified resin, a silicone resin, a silicone-modified resin, or a phenol resin.

Next, a method of manufacturing the light source device 60 according to the third embodiment will be described. First, the ceramic substrate 1 is prepared. The ceramic substrate 1 can be manufactured by the above-described method. After the ceramic substrate 1 is prepared, the light-emitting element 70 including the element body 71 and the element electrodes 72 is disposed on the ceramic substrate 1. At this time, the element electrodes 72 are electrically connected to electrically-conductive members 40 by using solder or the like such that the element electrodes 72 face the second surface 12.

In this manner, the light source device 60 according to the third embodiment can be manufactured.

In the third embodiment, instead of the ceramic substrate 1 according to the first embodiment, the ceramic substrate 2 according to the second embodiment can be used.

According to the present disclosure, a ceramic substrate that can improve heat dissipation, a light source device, a method of manufacturing a ceramic substrate, and a method of manufacturing a light source device can be provided.

Although embodiments have been described in detail above, the above-described embodiments are non-limiting examples, and various modifications and substitutions can be made to the above-described embodiments without departing from the scope described in the claims.

1. A ceramic substrate comprising:
a base having a first surface, a second surface opposite to the first surface, and a through hole having a first opening diameter at the first surface and a second opening diameter at the second surface, the first opening diameter being larger than the second opening diameter;
at least one solid particle disposed in the through hole; and
an electrically-conductive member disposed in the through hole, wherein
a thermal conductivity of the at least one solid particle is higher than a thermal conductivity of the electrically-conductive member, and
the electrically-conductive member is continuous between the first surface and the second surface.

2. The ceramic substrate according to claim 1, wherein the second opening diameter is smaller than an equivalent spherical diameter of the at least one solid particle.

3. The ceramic substrate according to claim 1, wherein the at least one solid particle is a polyhedron.

4. The ceramic substrate according to claim 1, wherein a volume of the at least one solid particle is 25% or more of a volume of the through hole.

5. The ceramic substrate according to claim 1, wherein the through hole has an inner lateral surface that is continuous from the first surface to the second surface, and the inner lateral surface is inclined at an angle of 80° or more and 89° or less with respect to the second surface.

6. The ceramic substrate according to claim 1, wherein an equivalent spherical diameter of the at least one solid particle is smaller than a thickness of the base.

7. The ceramic substrate according to claim 1, wherein the at least one solid particle is embedded in the electrically-conductive member.

8. The ceramic substrate according to claim 1, wherein the at least one solid particle includes at least one material selected from a group consisting of diamond, silicon carbide, boron nitride, nanocarbon, copper, and silver.

9. The ceramic substrate according to claim 1, wherein the at least one solid particle is:
a diamond particle; or
a composite particle that includes the diamond particle and a plating layer covering the diamond particle.

10. The ceramic substrate according to claim 1, wherein the electrically-conductive member includes sintered copper or sintered silver.

11. Alight source device comprising:
the ceramic substrate of claim 1; and
a light-emitting element including an element electrode,
wherein the electrically-conductive member of the ceramic substrate and the element electrode are electrically connected to each other.

12. The light source device according to claim 11, wherein the light-emitting element is disposed on the second surface.

13. A method of manufacturing a ceramic substrate, the method comprising:
preparing a base having a first surface, a second surface opposite to the first surface, and a through hole having a first opening diameter at the first surface and a second opening diameter at the second surface, the first opening diameter being larger than the second opening diameter;
disposing at least one solid particle in the through hole from a first surface side of the base;
disposing an electrically-conductive paste in the through hole after the disposing of the at least one solid particle in the through hole; and
forming an electrically-conductive member that is continuous between the first surface and the second surface by sintering the electrically-conductive paste, wherein
a thermal conductivity of the at least one solid particle is higher than a thermal conductivity of the electrically-conductive member.

14. The method of manufacturing the ceramic substrate according to claim 13, wherein the second opening diameter is smaller than an equivalent spherical diameter of the at least one solid particle.

15. The method of manufacturing the ceramic substrate according to claim 13, wherein
the preparing of the base includes preparing a first film attached to the first surface and having a first opening at a position overlapping the through hole, and a second film attached to the second surface and having a second opening at a position overlapping the through hole,
the disposing of the electrically-conductive paste includes disposing the electrically-conductive paste in the first opening and the second opening, and
before the forming of the electrically-conductive member, the first film and the second film are peeled off.

16. A method of manufacturing a light source device, the method comprising:
preparing the ceramic substrate manufactured by the method of claim 13; and
disposing a light-emitting element including an element electrode on the ceramic substrate,
wherein, in the disposing of the light-emitting element, the electrically-conductive member and the element electrode are electrically connected to each other.

17. The method of manufacturing the ceramic substrate according to claim 13, wherein the at least one solid particle is a polyhedron.

18. The method of manufacturing the ceramic substrate according to claim 13, wherein a volume of the at least one solid particle is 25% or more of a volume of the through hole.

19. The method of manufacturing the ceramic substrate according to claim 13, wherein the through hole has an inner lateral surface that is continuous from the first surface to the second surface, and the inner lateral surface is inclined at an angle of 80° or more and 89° or less with respect to the second surface.

20. The method of manufacturing the ceramic substrate according to claim 13, wherein an equivalent spherical diameter of the at least one solid particle is smaller than a thickness of the base.
